(19) United States
(12) Patent Application Publication
(10) Pub. No.: US 2026/0156968 A1
(43) Pub. Date: Jun. 4, 2026

(54) METHOD FOR PROCESSING AN OPTOELECTRONIC DEVICE AND OPTOELECTRONIC DEVICE

(71) Applicant: ams-OSRAM International GmbH, Regensburg (DE)

(72) Inventors: Christoph Klemp, Regensburg (DE); Andreas Biebersdorf, Regensburg (DE)

(21) Appl. No.: 18/703,987

(22) PCT Filed: Oct. 29, 2021
(86) PCT No.: PCT/EP2021/080209

§ 371 Date: Apr. 23, 2024

(51) Int. Cl. H10H 20/01; H10H 20/812; H10H 20/816; H10H 20/821

(52) U.S. Cl. CPC H10H 20/0137; H10H 20/017; H10H 20/018; H10H 20/019; H10H 20/032; H10H 20/812; H10H 20/816; H10H 20/821

(57) ABSTRACT

In an embodiment a method for processing an optoelectronic device includes providing a functional semiconductor layer stack on a growth substrate having an active layer for emitting light arranged between a first doped layer and a second doped layer, the second doped layer having a thickness, depositing a hard mask on the second doped layer, structuring the hard mask as to expose surface areas of the second doped layer, wherein the exposed surface areas are recessed with regard to a surface of the second doped layer beneath remaining portions of the hard mask and a remaining thickness of a material of the second doped layer at the exposed surface areas is less than 600 nm, diffusing a dopant into the material of the second doped layer at the exposed surface areas as to perform a quantum well intermixing within regions of the active layer beneath the exposed surface areas and applying a first contact material at least on unexposed areas of the doped second layer.

### CROSS-REFERENCE TO RELATED APPLICATIONS

This patent application is a national phase filing under section 371 of PCT/EP2021/080209, filed Oct. 29, 2021, which is incorporated herein by reference in its entirety.

### TECHNICAL FIELD

The present invention concerns a method for processing an optoelectronic device and an optoelectronic device.

### BACKGROUND

Optoelectronic devices with a diameter of its emitting surface of less than 70 μm and down to 1 μm are referred to as μ-LEDs. Such μ-LEDs have an emitting area of about 1 μm² to about 100 μm² and are configured to emit blue, red, and green light. Particularly, μ-LED for emitting red light are facing several challenges. They are usually based on a quaternary material system using Indium to shift the bandgap to lower energies. Indium in quaterny systems like InGaAlP causes a relatively large diffusion length for charge carriers, which results in an increased non radiative recombination at sidewall edges in smaller devices like the above mentioned μ-LEDs.

Various measures for improvement of light extraction efficiency (LEE) and reduction of non-radiative recombination of red μLED based in Indium have been implemented. Another issue concerns the small footprint of μLED when soldering its contact to a backplane. The amount of solder is very small, but even with this small volume, solder material may creep along the sidewall of the device causing a short-circuit.

### SUMMARY

Embodiments aim to address some of the above-mentioned issues to improve the performance of small optoelectronic devices.

One way of improving the performance of optoelectronic devices is based on Zn induced quantum well intermixing. During this approach Zn is diffused into areas of an active layer, causing a change in the bandgap energy. Proper positioning of mask layer and control of the process is required to ensure that quantum well intermixing takes place in areas, which are subsequently used for separating the devices. Still, while the performance is improved, the process time in MOVPE reactors, material and cost remains a crucial factor as does the creeping issue of solder material.

The inventors realized that changes in parameters for the quantum well intermixing approach while proper designing the functional layer stack of an optoelectronic device can further improve the efficiency of the device and reduce the creeping of solder or glue onto the sidewalls. In conventional devices using quantum well intermixing processes (QWI), the thickness of the doped layer, that is from its surface to the active layer is in the range of about 1000 nm. A plasma etching process for removing the hard mask usually also removes about 10% to 20% of the doped layer as well, prior to diffusing Zn from the exposed surface into the active region.

The inventors now propose to reduce further the thickness of the doped layer prior to the diffusion step, such that the distance from the surface to the active region is less than 60% of the original thickness. The deliberately reduced thickness results in a faster diffusion of Zn until it reaches the active region. Further, the overall amount of Zn or generally any dopant is reduced. It also has been surprisingly observed that, although sidewalls of material beneath remaining portions of the hard mask are exposed, the overall undesired lateral diffusion of Zn beneath the hard mask is still lower compared to the lateral diffusion of Zn when conventional QWI techniques are applied.

The reduced thickness may be in the range of less than 600 nm and in the range of 200 nm to 500 nm. The reduced thickness may increase carrier leakage at the top surface, which can partially be addressed by additional passivation or other processing steps. Nevertheless, there is a lower limit for the thickness in the range of less than 100 nm, i.e. at about 50 nm. The optimum of remaining thickness of the doped layer is dependent on other factors such as the doping profile, doping material and other parameters. The optimum thickness can vary for each device design with respect to its desired brightness and reliability.

The adjusted process step of removing the material in the doped layer also provides a larger step that supports to prevent creeping of solder material onto sidewalls of the later device, making an additional etching step obsolete to achieve the same effect.

The inventor proposes a method for processing an optoelectronic device, providing a functional semiconductor layer stack on a growth substrate. The layer stack includes an active layer configured for emitting light arranged between a first doped layer and a second doped layer. The second doped layer contains a certain thickness, particularly suitable for distributing the charge carrier along an area for light emission. A hard mask is deposited on the second layer and subsequently structured to expose surface areas of the second layer. In this regard, the structuring causes the exposed surface areas to be recessed with regard to the surface of the second layer beneath remaining portions of the hard mask. The recess is adjusted such that the remaining thickness of material of the second layer at the exposed surface areas is less than 600 nm, and particularly between 200 nm and 500 nm.

The reduced thickness enables an improved quantum-well intermixing process with less material required. A dopant is diffused into material of the second layer at the exposed areas to perform the quantum well intermixing within regions of the active layer beneath the exposed surface areas. Then, a first contact material is deposited at least on unexposed areas of the second layer.

The reduced thickness enables the quantum well intermixing process to achieve a better control of the depth and the diffusion time. In addition, less material is required, because the required diffusion depth is reduced. As a surprising side effect, it was observed that the lateral diffusion of Zn into areas beneath the remaining portions of the hard mask is reduced as well. This is of some benefit, because Zn changes the overall dopant level and may disturb the electrical parameters of the device. In addition, the area, in which quantum well intermixing occurs is better definable and the diffusion profile sharpened due to the reduced lateral diffusion.

In some instances, the remaining thickness in the exposed area is a certain percentage of the overall thickness and may for example lay in the range between 5% and 50% and in particular between 10% and 40%. It may also depend on the aspect ratio, that is the depth of the recess versus its diameter. In some aspects, the aspect ratio may be less than 1, but it is larger than in conventional techniques, in which the depth is smaller. In this regard, it may be possible to reduce the distance between two adjacent functional layer stacks, thus resulting in less space consumed for the quantum well intermixed areas.

Some aspects concern the diffusion process itself. For example, Zn may be deposited as a dopant on the exposed surface areas at a first temperature. In a next step, the dopant is diffused into the material of the second layer and into regions of the active layer beneath the exposed surface areas at a second temperature, the second temperature being higher than the first temperature. The hard mask acts as a diffusion stopper for the Zn, such Zn is not diffused into the second layer beneath the hard mask. Having two or more process steps for the actual deposition and diffusion of Zn into the active layer provides a better control of the diffusion depth.

In this regard, it may be possible to deposit the dopant, e.g. Zn in an isotropic process resulting in the deposition of Zn also on the sidewalls of the second layer beneath the hard mask. For an isotropic deposition process the aspect ratio may influence the material on the sidewalls and the main surface of the recess, respectively. Still, the thickness of such material may be significantly smaller than the Zn on the main surface in the recess. Alternatively, the deposition and/or the diffusion process can be made anisotropic, such that Zn or any other dopant is mainly deposited and diffused into the main surface of the recess and from there into the active region.

In some other aspect, the step of structuring the hard mask comprises depositing a photoresist layer on the hard mask, and subsequently structuring the photoresist to remove portions of it. By doing so, some areas of the hard mask are exposed, and the material of the hard mask is removed in an etching process. The etching process also removes material of the second layer. In some aspects, the etching process to remove the mask and material of the second layer is an anisotropic process, mainly etching in the vertical direction, but not laterally (or not significant). Suitable wet- or gas-phase etching can be used for removing the material of the second layer and the hard mask.

In some other aspect, a growth substrate is provided. The growth substrate may comprise a different lattice constant than the layers of the functional layer stack. In such occurrences, one or more sacrificial layers or other layers are deposited to adjust the lattice constant to the lattice of the functional layer stack. Sacrificial layers e.g. made of highly doped GaN may be proposed to adapt the lattice constant more easily. In some aspects, a current distribution layer is deposited on the growth substrate and/or the sacrificial layers. The current distribution layer may comprise GaAlP, GaAlN, InGaAlP or InGaAlN with an Aluminum content of about 40% to 60%, for example 55%.

The first doped layer, in particularly n-doped, is deposited on the current distribution layer and an active layer is grown on the first doped layer. Then, the second doped layer, in particularly p-doped, is deposited on the active layer. In this regard, the active layer can comprise a multi-quantum well structure having a plurality of alternating quantum barrier layer and quantum well layers, respectively. The quantum well layer and the barrier layers may comprise different thicknesses. For example, the thickness of the quantum well layer may be smaller than those of the adjacent quantum barrier layers. In any case the various layers of the active region may comprise a thickens in the range of a few nm to about 20 nm. In some instances, the quantum barrier layers comprise InGaAlP or InGaAlN with an Aluminum content between 50% and 100% and the quantum well layers comprise InGaAlP or InGaAlN with an Aluminum content between 0% and 40%. Higher Aluminum content increases the bandgap in the quaterny material system.

After the first contact material is applied, the functional layer stack may further be processed to implement one or more separate optoelectronic devices. In some instances, the functional layer stack is rebounded, for example by arranged and fixating the contact material on temporary substrate. This substrate referred to be temporary can also be a final substrate and may contain several functionalities. In any case, the growth substrate is removed either completely or at least partially after the rebonding process. In cases in which sacrificial layer are deposited on the growth substrate, those can be removed as well. In some instances, the sacrificial layer is deposited at least partially on the first contact material such that a pillar of the temporary substrate material can be formed supporting the functional layer stack.

A mesa structure is applied to the functional layer stack in a subsequent step to form cavities in the material of the functional layer stack between two unexposed areas, wherein quantum well intermixed areas are located at edges of the sidewalls. Mesa structuring the functional layer stack will form separate and individually contacted optoelectronic devices. The sidewalls of those devices are usually tapered by the structuring process. However, in some instances, the tapering is controlled to allow a coherent coverage by subsequent layers that are forming p-contact and p-reflector.

A second contact material can be applied on the first doped layer after the growth substrate is at least partially removed.

Another aspect concerns the optoelectronic device in accordance with the proposed principle, as initially outlined a vertical optoelectronic device comprises a functional layer stack having an active layer configured for emitting light arranged between a first n-doped layer and a second p-doped layer. A first contact is arranged on a surface of the second p-doped layer. A second contact is applied on a surface of the first n-doped layer. Based on the previous proposed processing method, areas of the second p-doped layer surrounding the first contact are recessed with regard to the second p-doped layer beneath the first contact, such that a thickness of the areas is less than 600 nm and in particular between 100 nm and 500 nm.

This increased depth of the recess has the benefit when the optoelectronic device is attached to a backplane, as solder material is prevented from creeping over the sidewalls. The creeping on sidewall would result in brightness reduction of the red pixel or even no function due to electrical short. The proposed device improves to increase yield of display and reduce overall costs.

In some instances, the device comprises a conductive layer applied on the first contact, the conductive layer extending along the sidewalls and partially onto surface of the recessed areas surrounding the first contact. The conductive layer may comprise ITO. Although such layer also extends in the recess, it has been observed that ITO layer usually requires certain layer between the semiconductor material and the ITO to be fully conductive. Such layers comprise doped GaAs, which can also be used as a hard mask during the quantum well intermixing process. In some further instances, a metallic layer, particularly comprising Gold is arranged on the conductive layer.

Due to mesa structuring, the sidewalls of the functional layer stack can be tapered such that a footprint of the p-doped layer is generally larger than the footprint of the n-doped layer. In other words, the area or size of the p-doped layer at the level of the recess is larger than the level of the n-doped layer. In some instances, the diameter of the optoelectronic device decreases in the emission direction. The tapered sidewalls are covered with a passivation layer in some instances or overgrown with semiconductor material.

In some other aspects of the vertical optoelectronic device, the n-doped layer comprises a doped current distribution layer. In cases of quaternary material system like InGaAlP or InGaAlN, the Al content may be in the range of 40% to 60% and in particular in the range of 55%. The current distribution layer can be adjacent to the second contact. the second contact may also comprise an outcoupling structure, e.g. by a roughened or porosified surface to improve the outcoupling of light generated in the active layer.

In some other aspects, the optoelectronic device comprises a quantum well intermixed area in regions of the active layer close to the edges of the device. These areas may have a lateral extension to about the projection of the first contact. in other words, the quantum well intermixed areas of the active layer extend beneath the areas of the second p-doped layer surrounding the first contact, that is the areas which are recessed with regard to the first contact.

The active layer of the vertical optoelectronic device may comprise a plurality of alternating quantum well layers and quantum barrier layers, the quantum barrier layers having a higher Aluminum content than the quantum well layers. For example, the aluminum content of the barrier layers may be in the range of 50% to 80% or even between 60% to 100%, while the Aluminum content of the quantum well layer is less than 50% and particularly less than 40%. In some instances, the quantum well layers are thinner than the quantum barrier layers.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a side view of a conventional functional layer stack;

FIGS. 2A and 2B illustrate side views of a functional layer stack processed in accordance with some aspects of the present disclosure;

FIG. 3A to 3D show several steps for processing one or more optoelectronic devices in accordance with some aspects of the proposed principle;

FIG. 4A to 4E illustrate further steps for processing one or more optoelectronic devices in accordance with some aspects of the proposed principle;

FIGS. 5A and 5B show some steps of rebonding and further processing optoelectronic devices having an increased contact level in accordance with some aspects of the present disclosure;

FIG. 6 illustrate a side view of two soldered conventional optoelectronic devices; and

FIG. 7 shows a side view of two soldered optoelectronic devices with an increased contact level in accordance with some aspects of the present disclosure.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

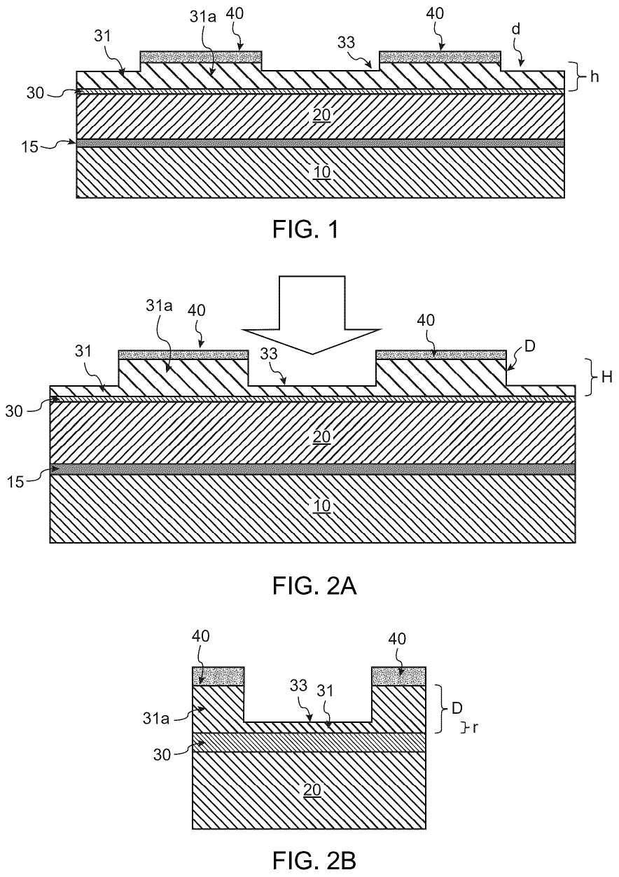

FIG. 1 shows a functional layer stack for processing a conventional optoelectronic devices. The functional layer stack is grown on a growth substrate 10 and includes a current distribution layer 15, an n-doped layer 20, an active layer 30 and p-doped layer 32. A hard mask 40 is provided on top of the p-doped layer 32 and subsequently structured as shown in FIG. 1.

As a result, the functional layer stack in this example comprises two hot mask areas 40 covering portions 31a of the second layer 32, while exposed portions 33 of layer 32 are consequently uncovered by hot mask layer 40. As illustrated in FIG. 1, an etching process is conducted to structure the hard mask 40 together with partially removing portions of the semiconductor material of second layer 32. Small pillar structures of unexposed material in areas 31a remain beneath the hard mask portions 40. A small sidewall of those portions 31a is located directly adjacent to the exposed surface area of the second layer.

In conventional quantum well intermixing techniques, the removal of the material in the exposed areas 33 of the second layer form a small recess in the range of a few 10 to hundred nanometers. Consequently, the remaining thickness of the second semiconductor layer 32 in those exposed areas is still significant and in the range between 70% to 90% of the original thickness. During of the diffusion process of Zn into portions of the active layer 30 beneath the exposed areas 33, the dopant diffuses vertically through the remaining material of the second layer and into the active region. In addition, a small lateral diffusion takes place resulting in an increased Zn dopant concentration along the edges of the unexposed areas 31a adjacent to the recesses.

The increased distance between the surface of the exposed areas 33 and portions of the active layer 30 requires a tight control of the diffusion process over the whole processing time. In addition to the tight temperature control, material consumption of Zn as a dopant is substantial as the dopant is deposited within the remaining material of the second layer in the exposed areas as well as in portions of the active layer 30. The previously performed ICP etching process is mainly used to define the p-contact area with a hard mask 40 covering the portions 31a and the diffusion area surrounding the respective p-contact. The remaining thickness of the semiconductor layer is in the range of several hundred nanometers and as explained above 70% to 90% of the overall thickness of the second layer.

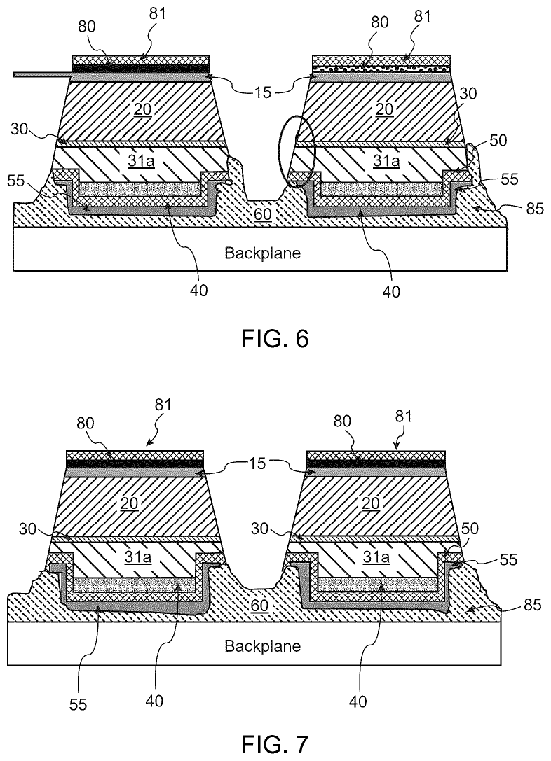

FIG. 6 illustrates two finished processed conventional optoelectronic devices after arranging and attaching it to a backplane of a display. Each optoelectronic device is implemented as a vertical LED with a first contact 55 and 40 adjacent to the backplane, and a second contact 80 and 81 on the opposite side also forming the light emission surface. As illustrated with regards to FIGS. 5A and 5B below, the optoelectronic devices containing various contact layers of gold, ITO, and other material to provide an electrical contact between the backplane and the active layer 30.

As shown, a solder material 60 is located between the backplane and the bottom surface 55 of the first contact of each optoelectronic device. Each optoelectronic device comprises a small recess caused by the previously etching process formed during the quantum well intermixing step, and during an additional etching process while further processing the device. This causes a step between the bottommost portion of layer 55 (forming the contact) and the portion adjacent to the contact. As shown by the red circle the solder material may creep along the sidewall of the respective optoelectronic devices and get in electrical contact with the semiconductor layer 32 along the sidewall. While an electric short circuit in such cases can be prevented by an additional passivation layer on the sidewalls, the solder material creeping on the sidewall may change the respective optical and electrical behaviour of the optoelectronic device. The creeping is caused by slight variations of the amount of solder material 60 on the backplane as well as of the pressure of the device when positioning the device on the backplane during its manufacture.

FIG. 2A shows an improvement in accordance with the proposed principle for processing method one or more optoelectronic devices. FIG. 2B illustrates a more detailed view of the processing results. In contrast to conventional techniques, the ICP or wet etching process for removing portions of hard mask 40 is extended such that a significant recess is formed in the second layer 32. In other words, material of the second layer 31 is removed from unexposed portions of the second layer until only a few hundred nanometers of the second layer 31 or even less material remains.

The removal of additional material of layer 32 will result in a significantly larger and deeper recess with sidewalls of second layer 31a beneath the hard mask 40 being exposed. The remaining the thickness of the second layer in those areas 33 is less than 600 nm and may range from approximately 100 nm to about 500 nm. In cases, in which the overall thickness of layer 33 is about a thousand nanometers, the remaining sickness therefore ranges between 10% to about 50% or less of the overall thickness H.

FIG. 2B illustrates a more detailed view of the recess after the ICP or wet etching process. As shown, the thickness of layer 32 between of the exposed surface area 33 and active layer 30 is significantly reduced without any of the sickness are remaining. The aspect ratio of the recess, that is, its diameter versus its depth is about 3 to 4 times larger than those recesses formed by conventional techniques. Consequently, portions of the sidewall of the area 31a beneath the hard mask 40 are exposed. In the present visualized example, the sidewalls a very steep and run virtually vertical towards the active layer 30. However, the etching process may also cause a tapered sidewall and can be controlled to follow a certain direction. This will allow to obtain a more controlled diffusion length and diffusion depth of the dopant during the quantum well intermixing process.

FIG. 7 illustrates two optoelectronic devices processed in accordance with the proposed principle for use in a display. The devices are arranged on the backplane with solder material contacting the bottommost layer 55 of the first contact of the respective devices. In the present example, the portions directly adjacent to the respective first contacts are recessed with a large depth compared to the conventional devices as illustrated in FIG. 6. Consequently, additional space by the respective recesses is provided as the thickness of semiconductor layer 31 close to the edges of the respective optoelectronic devices is reduced. The additional space acts as a spare reservoir during squeeze out of the solder material 60 from the backplane into the adjacent space. The spare reservoir for the solder material 60 prevents the solder from creeping or being pushed onto the sidewalls of the optoelectronic device. The threat of a short circuit is reduced, and a brightness drop caused the by solder material on the sidewalls of the optoelectronic device is largely prevented.

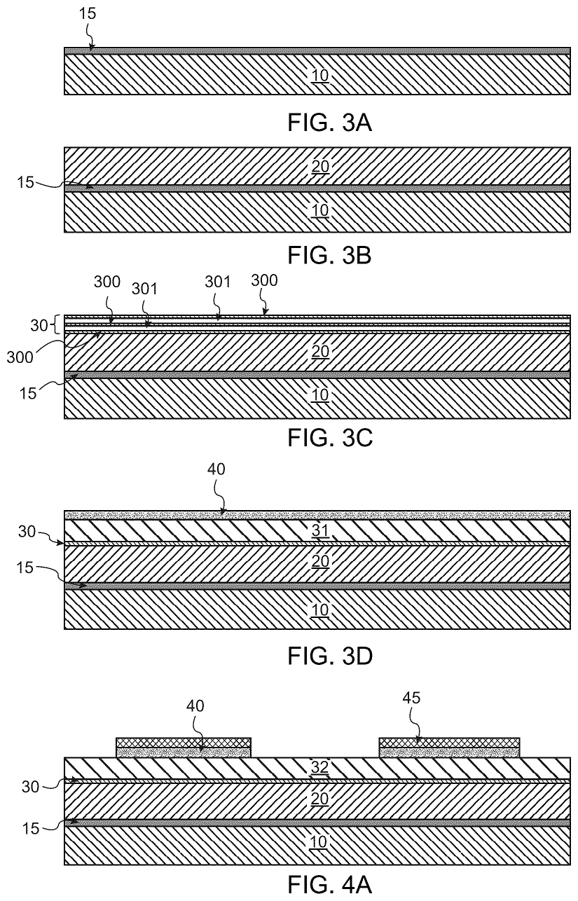

FIGS. 3A to 3D as well as 4A to 4E illustrates various steps of a method of processing an optoelectronic device in accordance with some aspects of the proposed principle. FIG. 3A shows the initial steps of the processing method, in which a growth substrate 10 is provided. The growth substrate 10 comprises GaAs material, Sapphire, or any other suitable growth material. In some instances, the growth substrate comprises a lattice constant, which is different from the lattice constant of the subsequently grown semiconductor layers. Sacrificial layers or other structures are provided to compensate for the lattice mismatch. As presented in FIG. 3A, a first current distribution layer 15 is arranged on the growth substrate 10. The current distribution layer 15 may include such sacrificial and other adjustment layers, as indicated above, and comprises highly doped semiconductor material to provide the required low resistance value.

Current distribution layer 15 may also include an aluminum content of about 50% to 60% and in particularly about 55% in quarterny semiconductor systems like InGaAlP or InGaAlN. Current distribution layer 15 also provides a smoothened surface. Then, the first n-doped semiconductor layer 20 is deposited on the current distribution layer 15, as shown in FIG. 3B. The n-doped semiconductor layer comprises a dopant profile adjusted for the subsequently grown active layer to ensure a good charge carrier transport into active layer region 30. It also comprises different aluminum contents to adjust the bandgap to the desired value.

In FIG. 3C, the various process steps for forming the active layer 30 are illustrated. Active layer 30 is formed as a multi-quantum well structure comprising a plurality of alternating barrier layers 300 and quantum well layers 301. In the present example, 3 barrier layers 302 quantum the layers 301 are illustrated. Barrier layers as well as quantum well layers are both based on InGaAlP or InGaAlN material, but comprise different aluminum contents. For example, the aluminum content for the barrier layers is in the range between 50% to 70% or 90%, while the respective quantum well layers comprise an aluminum content of about 0% to 40%. As a result, the bandgap of the quantum well layers are smaller than the respective bandgap of the barrier layers due to the increased aluminum content. While in the present example, the active layer 30 is formed as a multi-quantum well structure, one skilled in the art may recognize that other formations for the active layer are suitable without departing from the scope of the proposed principle.

In a subsequent step, a p-doped semiconductor material 31 is deposited and grown on the active layer 30. Similar as in the growth for the n-doped semiconductor layer 20, the p-doped semiconductor layer 31 comprises a dopant gradient or dopant profile suitable to transport charge carriers into the active layer 30. On the top surface of the p-doped layer 31, a hard mask 40 is subsequently grown. Hard mask 40 comprises GaAs or any other suitable material. In some cases, it is also highly doped and can therefore be used as conductive contact layer for the semiconductor layers beneath. GaAs material will block the diffusion of Zn into the semiconductor material beneath.

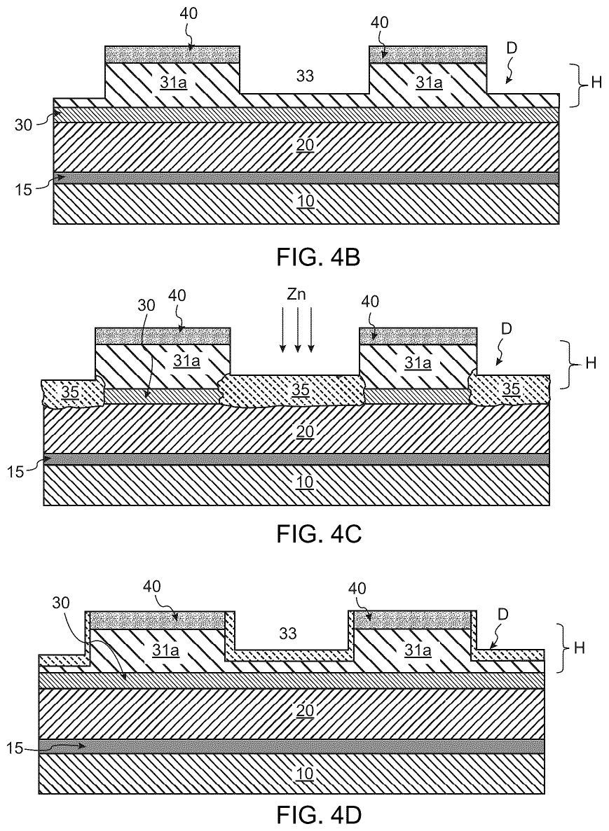

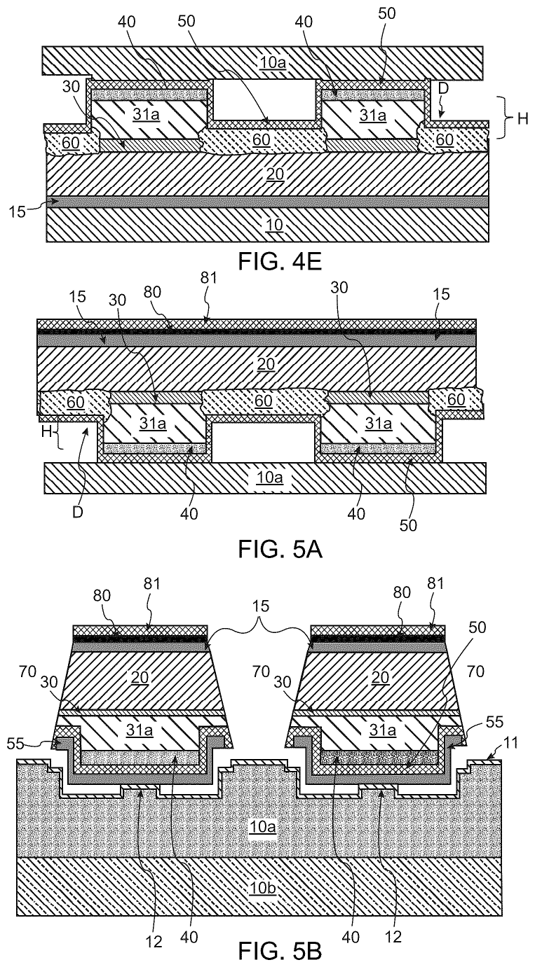

The hard mask layer 40 is now structured, by providing a photo resist layer 45 on the top surface of the hard mask. Photo resist layer 45 is partially exposed and subsequently removed to expose portions of the hard mask beneath. Then an ICP or another suitable etching process is performed to remove the exposed hard mask portions. The resulting structure is illustrated in FIG. 4A.

However, as illustrated in FIG. 4B, the etching the process to remove the hard mask portions is continued such that the exposed surface of the second semiconductor layer 31 is etched to form enlarged recesses in the second layer. The etching process is continued until only a few hundred nanometers of the second layer closer to the active region 30 is left intact.

The resulting depth of the recess is significantly larger than in conventional etching techniques and may cause a recess, in which is about 50% to about 90% of the overall thickness of the second layer is removed.

In a subsequent step, a deposition and diffusion process with Zn as a dopant for the quantum well intermixing process is performed. FIGS. 4C and 4D illustrates two alternatives of such process to achieve the quantum well intermixing.

In FIG. 4C, the dopant Zn is provided as a directed flow to be deposited on the surface of the exposed area 33 of the second layer. The dopant is deposited on the surface and diffused to directly into the material of the second layer and subsequently into material of the active layer 30 beneath the exposed areas. As illustrated in FIG. 4C, the dopant may also partially diffuse into the undoped layer 20 beneath the active region, but this process is tightly controlled by adjusting the respective temperature and processing time, as well as the concentration of the dopant. In any case, a quantum well intermixing is formed in areas 35 of active area 30 beneath the exposed portions 33 of the second layer.

The quantum well intermixed area also extends slightly laterally beneath the hard mask portions 40, as shown, and as such also covers a small portion of active layer 30 beneath the hard mask. In addition, Zn as a dopant also diffuses laterally into material 31a beneath the hard mask portions 40 and causes a concentration gradient in areas close to the sidewalls.

FIG. 4D illustrates an alternative approach for the deposition and diffusion process, respectively and for the quantum well intermixing process. In this example, Zn as a dopant is isotropically formed on the top surfaces of the hard mask 40 (not shown herein), as well as on the exposed surface 33 of the second layer in the recess and on the sidewalls on layer 31a. However, the thickness deposited on the sidewalls is smaller than the thickness of the dopant deposited on the bottom surface of the recess. The deposition of Zn as a dopant occurs at a first temperature, which is high enough to an facilitate the deposition of Zn on the surface, but too low trigger a diffusion of Zn into the material of the second layer.

In a subsequent step, the temperature is increased, allowing the dopant to diffuse into the material of the second layer and subsequently into portions of active layer 30 beneath the respective recesses. This process of using two or more different temperatures to differentiate between deposition and diffusion enables a better control of the depth and the concentration profile of the dopant within the active region during the quantum well intermixing process. Further, the diffusion edges that is the interface between material 31a beneath the hard mask 40 and the quantum well intermixed areas 35 are better defined and provide a stepper potential barrier for the respective charge carriers.

FIG. 4E now illustrates a subsequent processing step of the optoelectronic devices and the functional layer stack. In this process step, the functional layer stack is prepared for a re-bonding process. This purpose, a conductive layer 50 is deposited on the remaining portions of hard mask 40, the sidewalls of the respective first contacts as well as on the quantum well intermixed areas 60. The conductive layer 50 comprises ITO. On the GaAs hard mask 40, the ITO has a low interface resistance and is particularly suitable to inject charge carriers into the hard mask material. In recess areas above the quantum well intermixed portions the ITO layer can either be removed or left as residual layer. The recesses are then filled up with a sacrificial material which also covers the topmost portions of conductive layer 50. These additional layers, not shown herein, a subsequently structured to form supporting pillars for the optoelectronic devices to be separated in a subsequent step. The pillars allow an easy removal of the respective optoelectronic devices from the substrate and enable placement on the backplane of a display and the like. After structuring and preparation of the sacrificial layers, temporary substrate 10a is attached to the functional layer stack for further processing of the optoelectronic devices.

FIG. 5A shows a result of the next processing step, in which the functional layer stack is turned upside down such that the functional layer stack now rests on the temporary substrate 10A. Growth substrate 10 is now completely removed in the present example to open the underlying current distribution layer 15. In an alternative embodiment, the growth substrate is thinned to a relatively small level in cases the growth substrate can also act as a current transport or current distribution layer.

In addition, any sacrificial layer between the current distribution layer 15 into the growth substrate 10 may be removed. In a subsequent step, the top portion of the current distribution layers 15 is covered with respective contact layers 80 and 81 to provide a good contact to the semiconductor material. The contact layers 80 and 81 include an alloy containing Gold and Germanium for layer 80, followed by a transparent ITO layer 81. The surface of ITO layer 81 is roughened to act as an emission surface for the respective optoelectronic devices.

In a subsequent step, the respective topmost surface of the ITO layer 81 is covered by a photo resist layer and subsequently structured as to form mesa recesses 70 in the functional layer stack. The material of the respective contact layers 80 and 81, the current distribution layer 15, as well as the semiconductor functional layer stack is removed portions above the quantum well intermixed areas 60. This will open a hole and give access to the sacrificial layers filling the recesses between the temporary substrate 10a and the first contacts of the respective optoelectronic devices.

The resulting Mesa structure 70 comprises a tapered shape with a decreasing diameter towards the temporary substrate 10a. The sidewalls of the separate optoelectronic devices are now passivated. In a subsequent selective wet etching step, the sacrificial layer between first contact layer 55 and temporary substrate 10a is removed through the mesa openings 70, leaving pillar structures 12 behind. The pillars 12 support the optoelectronic devices and act as an anchoring point for the devices. They comprise a relatively low adhesion force, thus allowing to easily remove as the respective optoelectronic devices. As outlined in FIG. 5B, the portions surrounding the first contact with hard mask portions 40 comprise a relatively steep and large edge caused by the deep etching process in preparation of the quantum well intermixing. The distance between the surface of layer 55 in those areas and the top surface of layer 10a is slightly enlarged giving an easier and faster access to the sacrificial material during the etching process. The increased distance may also reduce the risk of damages during lift-off of the devices, particularly in cases, in which the lift-off comprises a horizontal force component.

1.-19. (canceled)

20. A method for processing an optoelectronic device, the method comprising:
providing a functional semiconductor layer stack on a growth substrate having an active layer for emitting light arranged between a first doped layer and a second doped layer, the second doped layer having a thickness;
depositing a hard mask on the second doped layer;
structuring the hard mask as to expose surface areas of the second doped layer, wherein the exposed surface areas are recessed with regard to a surface of the second doped layer beneath remaining portions of the hard mask and a remaining thickness of a material of the second doped layer at the exposed surface areas is less than 600 nm;
diffusing a dopant into the material of the second doped layer at the exposed surface areas as to perform a quantum well intermixing within regions of the active layer beneath the exposed surface areas; and
applying a first contact material at least on unexposed areas of the doped second layer, wherein diffusing the dopant comprises:
depositing Zn as a dopant on the exposed surface areas at a first temperature, and
diffusing the dopant into material of the second doped layer and into regions of the active layer beneath the exposed surface areas at a second temperature, the second temperature being higher than the first temperature.

21. The method according to claim 20, wherein diffusing the dopant comprises a directed deposition of the dopant onto the exposed surface areas.

22. The method according to claim 20, wherein diffusing the dopant comprises depositing the dopant onto sidewalls of the unexposed areas of the second doped layer, and wherein a material deposited on the sidewalls is less thick than a material deposited on the exposed surface areas.

23. The method according to claim 20, wherein structuring the hard mask comprises:
depositing a photoresist layer on the hard mask,
structuring the photoresist layer and removing portions of the photoresist layer, and
removing exposed portions of the hard mask and the material of the second doped layer by an etching process.

24. The method according to claim 20, wherein providing the functional semiconductor layer stack on the growth substrate comprises:
providing the growth substrate,
depositing a current distribution layer on the growth substrate,
depositing the first doped layer on the current distribution layer,
depositing the active layer, and
depositing the second doped layer on the active layer.

25. The method according to claim 20, wherein depositing the active layer comprises depositing a plurality of alternating quantum well layers and quantum barrier layers.

26. The method according to claim 25, wherein the quantum barrier layers comprise InGaAlP or InGaAIN with an aluminum content between 50% and 100%, inclusive, and wherein the quantum well layers comprise InGaAlP or InGaAlN with an aluminum content between 0% and 40%, inclusive.

27. The method according to claim 20, further comprising:
rebonding the functional semiconductor layer stack by arranging the first contact material on a temporary substrate;
removing the growth substrate at least partially; and
mesa structuring the functional semiconductor layer stack to form cavities in the material of the functional semiconductor layer stack between two unexposed areas,
wherein quantum well intermixed areas are located at edges of sidewalls.

28. The method according to claim 27, wherein the sidewalls are tapered in a direction of the temporary substrate.

29. The method according to claim 27, wherein rebonding comprises depositing a sacrificial layer at least partially on the first contact material so that a pillar of a temporary substrate material is formed supporting the functional semiconductor layer stack.

30. The method according to claim 20, further comprising, after removing the growth substrate at least partially, applying a second contact material on the first doped layer.
